(19) United States
(12) Patent Application Publication
(10) Pub. No.: US 2024/0047248 A1
(43) Pub. Date: Feb. 8, 2024

(54) ADAPTIVE MODEL TRAINING FOR PROCESS CONTROL OF SEMICONDUCTOR MANUFACTURING EQUIPMENT

(71) Applicant: Lam Research Corporation, Fremont, CA (US)

(72) Inventors: Dipongkar Talukder, Sherwood, OR (US); Yan Zhang, Fremont, CA (US); Ye Feng, Portland, OR (US); Jeffrey D. Bonde, Redwood City, CA (US)

(21) Appl. No.: 18/258,497

(22) PCT Filed: Dec. 13, 2021
(86) PCT No.: PCT/US2021/063055

§ 371 Date: Jun. 20, 2023

Related U.S. Application Data
(60) Provisional application No. 63/199,340, filed on Dec. 21, 2020.

(51) Int. Cl. H01L 21/67; H01L 21/66

(52) U.S. Cl. CPC H01L 21/67253; H01L 22/12

(57) ABSTRACT

Various embodiments herein relate to systems and methods for adaptive model training. In some embodiments, a computer program product for adaptive model training is provided, the computer program product comprising a non-transitory computer readable medium on which is provided computer-executable instructions for: receiving, from a plurality of process chambers, ex situ data associated with wafers fabricated using the process chambers and in situ measurements, wherein a first machine learning model is used to predict the ex situ data using the in situ measurements; calculating a metric indicating an error associated with the first machine learning model; determining whether to update the first machine learning model; and generating a second machine learning model using the ex situ data and the in situ measurements.

### INCORPORATION BY REFERENCE

A PCT Request Form is filed concurrently with this specification as part of the present application. Each application that the present application claim benefit of or priority to as identified in the concurrently filed PCT Request Form is incorporated by reference herein in its entirety and for all purposes.

### BACKGROUND

Semiconductor manufacturing equipment, such as a process chamber, may use in situ measurements for process control during fabrication of a wafer. For example, in situ measurements may be used to accurately control an etch depth, a deposition depth, etc. during wafer fabrication. In some cases, a machine learning trained model can be used to convert in situ measurements to predictions of measurements that are in turn used for process control. However, such a model may become out of specification, for example, due to drift of the process chamber. It can be difficult to detect when a model has become out of specification. Moreover, it can be computationally intensive to re-train the model.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor implicitly admitted as prior art against the present disclosure.

### SUMMARY

Disclosed herein are methods and systems for process control of semiconductor manufacturing equipment.

In accordance with some embodiments of the disclosed subject matter, a computer program product for adaptive model training is provided, the computer program product comprising a non-transitory computer readable medium on which is provided computer-executable instructions for: receiving, from a plurality of process chambers, ex situ data associated with wafers fabricated using the process chambers and in situ measurements, wherein the plurality of process chambers use a first machine learning model for process control during fabrication of wafers by the plurality of process chambers, wherein the first machine learning model is used to predict the ex situ data using the in situ measurements, and wherein the ex situ data for a wafer indicates a characteristic of the wafer post-fabrication; calculating a metric indicating an error associated with the first machine learning model using the ex situ data from the plurality of process chambers; determining whether to update the first machine learning model based on the metric indicating the error; and in response to determining that the first machine learning model is to be updated, generating a second machine learning model using the ex situ data and the in situ measurements received from the plurality of process chambers.

In some embodiments, the ex situ data is ex situ metrology data measured post-fabrication for a subset of fabricated wafers.

In some embodiments, the ex situ data includes geometric information related to features of a wafer.

In some embodiments, the ex situ data includes Optical Critical Dimension (OCD) information that indicates a depth of the features of the wafer.

In some embodiments, the ex situ data comprises an etch depth.

In some embodiments, the first machine learning model and the second machine learning model are each used to generate predicted OCD values using the in situ measurements.

In some embodiments, the metric indicating the error comprises a cumulative sum of errors of the plurality of process chambers.

In some embodiments, determining whether to update the first machine learning model comprises determining whether the cumulative sum of errors exceeds a control threshold.

In some embodiments, the metric indicating the error comprises a variance of errors of the plurality of process chambers.

In some embodiments, determining whether to update the first machine learning model comprises determining whether the variance of errors exceeds a control threshold.

In some embodiments, determining whether to update the first machine learning model comprises determining that a cumulative sum of error of the plurality of process chambers exceeds a control threshold and that a variance of errors of the plurality of process chambers exceeds the control threshold.

In some embodiments, generating the second machine learning model comprises training a machine learning model using a training set constructed from the ex situ data received from the plurality of process chambers and the in situ measurements received from the plurality of process chambers.

In some embodiments, the in situ measurements comprise reflectance data.

In some embodiments, the computer program product further comprises instructions for: determining whether the second machine learning model satisfies criteria to be deployed to the plurality of process chambers; and in response to determining that the second machine learning model satisfies criteria to be deployed to the plurality of process chambers, transmitting the second machine learning model each of the plurality of process chambers.

In some embodiments, determining whether the second machine learning model satisfies the criteria to be deployed comprises evaluating the first machine learning model and the second machine learning model on a test set of ex situ data and in situ measurements.

In some embodiments, the criteria comprises better predictive performance of the second machine learning model on the test set of ex situ data and in situ measurements compared to the first machine learning model.

In some embodiments, ex situ data included in the test set comprises ex situ data collected after the determination that the first machine learning model is to be updated.

In some embodiments, the ex situ data included in the test set comprises a first subset of ex situ data collected before the determination that the first machine learning model is to be updated and a second subset of ex situ data collected after the determination that the first machine learning model is to be updated.

In some embodiments, determining whether the second machine learning model satisfies the criteria to be deployed comprises determining that an error of the second machine learning model in predicting ex situ data included in a test set is below a threshold.

In some embodiments, the computer program product further comprises instructions for. (i) in response to determining that the second machine learning model does not satisfy criteria to be deployed to the plurality of process chambers, generating a third machine learning model; (ii) determining whether the third machine learning model satisfies the criteria to be deployed to the plurality of process chambers; repeating (i) and (ii) until it is determined that the third machine learning model satisfies the criteria to be deployed to the plurality of process chambers, and in response to determining that the third machine learning model satisfies the criteria to be deployed to the plurality of process chambers, transmitting the third machine learning model to each of the plurality of process chambers.

In some embodiments, repeating (i) and (ii) until it is determined that the third machine learning model satisfies the criteria to be deployed comprises repeating (i) and (ii) until it is determined that the third machine learning model is optimal.

In some embodiments, a training set used to generate the second machine learning model is smaller than a training set used to generate the third machine learning model.

In some embodiments, the training set used to generate the third machine learning model comprises newer ex situ data and in situ measurements than the training set used to generate the second machine learning model.

In accordance with some embodiments of the disclosed subject matter, a computer program product for using adaptively trained models is provided, the computer program product comprising a non-transitory readable medium on which is provided computer-executable instructions for: transmitting, to a model training system, ex situ metrology data corresponding to a wafer fabricated using a first machine learning model received from the model training system, wherein the first machine learning model is used for process control of a process chamber that fabricated the wafer; receiving, from the model training system, a second machine learning model for use in process control of the process chamber, wherein the second machine learning model was generated by the model training system using ex situ metrology data received from a plurality of process chambers and in situ on-wafer optical data measured by the plurality of process chambers; and replacing the first machine learning model with the second machine learning model.

In some embodiments, the computer program product further comprises instructions for receiving, from the model training system, a message that an error associated with the first machine learning model has exceeded a threshold.

In some embodiments, the computer program product further comprises instructions for transmitting, to the model training system, second ex situ metrology data corresponding to a second wafer fabricated using the first machine learning model prior to receiving the machine learning model from the model training system.

In some embodiments, the ex situ metrology data is used to determine that an error associated with the first machine learning model has exceeded a threshold, and wherein the second ex situ metrology data is used to determine that the second machine learning model is to replace the first machine learning model.

### BRIEF DESCRIPTION OF THE DRAWINGS

FIG. 1 presents a schematic diagram of use of a library training system in accordance with some embodiments of the disclosed subject matter.

FIGS. 2A and 2B present operations of a processor for adaptive library training in accordance with some embodiments of the disclosed subject matter.

FIG. 3 shows example data for triggering library training in accordance with some embodiments of the disclosed subject matter.

FIGS. 4A and 4B show example schematic diagrams for allocating training sets and test sets for library training in accordance with some embodiments of the disclosed subject matter.

FIG. 5 shows a table that illustrates an example of library retraining in accordance with some embodiments of the disclosed subject matter.

FIG. 6 shows an example flowchart for adaptive library training in accordance with some embodiments of the disclosed subject matter.

FIG. 7 presents an example computer system that may be employed to implement certain embodiments described herein.

### DETAILED DESCRIPTION

### Terminology

The following terms are used throughout the instant specification:

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. Besides semiconductor wafers, other work pieces that may take advantage of the disclosed embodiments include various articles such as printed circuit boards, magnetic recording media, magnetic recording sensors, mirrors, optical elements, micro-mechanical devices and the like. The work piece may be of various shapes, sizes, and materials.

A “semiconductor device fabrication operation” as used herein is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and material additive processes, such as deposition processes (e.g., physical vapor deposition, chemical vapor deposition, atomic layer deposition, electrochemical deposition, electroless deposition). In the context of etch processes, a substrate etch process includes processes that etch a mask layer or, more generally, processes that etch any layer of material previously deposited on and/or otherwise residing on a substrate surface. Such an etch process may etch a stack of layers in the substrate.

“Manufacturing equipment” refers to equipment in which a manufacturing process takes place. Manufacturing equipment often has a process chamber in which the workpiece resides during processing. Typically, when in use, manufacturing equipment perform one or more semiconductor device fabrication operations. Examples of manufacturing equipment for semiconductor device fabrication include deposition reactors such as electroplating cells, physical vapor deposition reactors, chemical vapor deposition reactors, and atomic layer deposition reactors, and subtractive process reactors such as dry etch reactors (e.g., chemical and/or physical etch reactors), wet etch reactors, and ashers.

“Fleet” as used herein refers to a group of process chambers that are executing the same semiconductor fabrication recipe (e.g., the same etching process, the same deposition process, etc.). Note that a fleet of process chambers can include any suitable number (e.g., five, ten, fifteen, twenty, thirty, and/or any other suitable number of process chambers). In some embodiments, all members of the fleet are configured with the same components; e.g., the same RF generators, the same chamber wall dimensions, the same showerhead designs, etc.

“Reflectance data” as used herein refers to optical reflectance data measured using one or more optical sensors of a process chamber. Reflectance data can be in situ, on-wafer measurements collected during fabrication of a wafer, for example, for use in process control. In some embodiments, reflectance data can indicate any suitable information, such as an intensity of reflected light as a function of time and/or wavelength of light emitted from any suitable light source. For example, in some embodiments, the reflectance data can correspond to light reflected from emitted light that is directed at a spot or point on a wafer during fabrication.

“Metrology data” as used herein refers to data produced, at least in part, by measuring features of a processed substrate. Note that, as described herein, metrology data may refer to ex situ measurements. That is, the metrology measurements may be made before or after performing the semiconductor device manufacturing operation. In some embodiments, metrology data is produced by a metrology system performing microscopy (e.g., scanning electron microscopy (SEM), transmission electron microscopy (TEM), scanning transmission electron microscopy (STEM), reflection electron microscopy (REM), atomic force microscopy (AFM)) or optical metrology on the etched substrate.

In some embodiments, the metrology data is produced by performing reflectometry, dome scatterometry, angle-resolved scatterometry, small-angle X-ray scatterometry and/or ellipsometry on a processed substrate. In some embodiments, the metrology data includes spectroscopy data from, e.g., energy dispersive X-ray spectroscopy (EDX). In some cases, optical metrology is performed using a stand-alone or integrated optical metrology tool configured to accurately characterize one or more properties of a fabricated or partially fabricated electronic device. Such optical metrology tool may be configured to produce a small beam spot (e.g., about 5 mm or smaller diameter) on a substrate surface. In some embodiments, the metrology data can include Optical Critical Dimension (OCD) information corresponding to a feature. As a specific example, in some embodiments, the OCD information can indicate an etch depth.

A metrology system may obtain information about dimensions (e.g., size, depth, width, etc.) of various features, such as edges, vias, trenches, etc. A metrology system may obtain information about materials contained in a substrate or a layer on a substrate. Such information may include optical information (e.g., extinction coefficient and/or refractive index), chemical information (e.g., chemical composition and/or atomic composition), morphological information such as crystal structure, and the like.

Note that, as used herein, metrology data can be collected ex situ for a wafer before or after a fabrication operation is performed on the wafer. In some embodiments, metrology data can be collected on a subset of wafers fabricated by a particular process chamber (e.g., every tenth wafer, every fifteenth wafer, etc.).

“Process control” as used herein refers to setting, adjusting, and/or maintaining parameters of a process chamber during fabrication of a wafer by the process chamber to achieve target wafer specifications, such as a target etch depth, a target side wall angle, etc. “Endpoint control” is an example of process control, where a determination of whether a target endpoint (e.g., a target etch depth) has been reached.

A “machine learning model” as used herein is a trained computational algorithm that has been trained to build a computational model of relationships between data points. A trained machine learning model can generate outputs based on learned relationships without being explicitly programmed to generate the output using explicitly defined relationships.

Examples of machine learning models include regression models, autoencoder networks (e.g., a Long-Short Term Memory (LSTM) autoencoder, a convolutional autoencoder, a deep autoencoder, a variational autoencoder, and/or any other suitable type of autoencoder network), neural networks (e.g., a convolutional neural network, a deep convolutional network, a recurrent neural network, and/or any other suitable type of neural network), clustering algorithms (e.g., nearest neighbor, K-means clustering, and/or any other suitable type of clustering algorithms), random forests models, including deep random forests, restricted Boltzmann machines, Deep Belief Networks (DBNs), recurrent tensor networks, and gradient boosted trees.

Note that some machine learning models are characterized as “deep learning” models. Unless otherwise specified, any reference to machine learning models herein includes deep learning embodiments. A deep learning model may be implemented in various forms, such as by a neural network (e.g., a convolutional neural network). In general, though not necessarily, it includes multiple layers. Each such layer includes multiple processing nodes, and the layers process in sequence, with nodes of layers closer to the model input layer processing before nodes of layers closer to the model output. In various embodiments, one layers feeds to the next, etc.

In various embodiments, a deep learning model can have significant depth. In some embodiments, the model has more than two (or more than three or more than four or more than five) layers of processing nodes that receive values from preceding layers (or as direct inputs) and that output values to succeeding layers (or the final output). Interior nodes are often “hidden” in the sense that their input and output values are not visible outside the model. In various embodiments, the operation of the hidden nodes is not monitored or recorded during operation.

The nodes and connections of a deep learning model can be trained and retrained without redesigning their number, arrangement, etc.

As indicated, in various implementations, the node layers may collectively form a neural network, although many deep learning models have other structures and formats. In some instances, deep learning models do not have a layered structure, in which case the above characterization of “deep” as having many layers is not relevant.

It should be noted that the techniques described herein for adaptive model training can be applied with respect to any type of machine learning model.

A trained machine learning model can be used for process control. For example, a trained machine learning model can be used to predict ex situ data from in situ measurements for in situ process control. In some such embodiments, the trained machine learning model can include a collection of coefficients that are used to predict ex situ data from in situ measurements, where the coefficients are the result of training using a machine learning algorithm. In instances in which the trained machine learning model is a regression model, the collection of coefficients may correspond to coefficients for terms in the regression model. Note that a trained machine learning model used for in situ process control is sometimes referred to herein as a “library.”

In some embodiments, a machine learning model or a library that is used to predict ex situ data using in situ measurements for in situ process control can be trained by a “library training system.” As used herein, a “library training system” can be configured to train a machine learning model or a library using metrology data received from multiple process chambers, which may be process chambers in a fleet. In some embodiments, the library training system can update a library, for example, in response to determining that a library in use by the fleet of process chambers is out of date (e.g., due to process drift of the process chambers, passage of in service time, and/or for any other reason(s)). In some embodiments, the library training system can be configured to then transmit an updated library to some or all members of the fleet of process chambers.

In some embodiments, a library can be trained by the library training system to minimize an error between predicted ex situ values and ground truth ex situ values indicated in the metrology data. For example, the library can be trained to minimize an error between predicted OCD information and ground truth OCD values indicated in the ex situ metrology data.

“Optical library” as used herein refers to a collection of coefficients or other information that can be used to generate predicted information for process control of a process chamber using measured in situ data, such as reflectance data. Note that an optical library as used herein is an example of a trained machine learning model used for in situ process control. For example, in some embodiments, an optical library can be used to predict ex situ measurements based on in situ measurements using a collection of coefficients in an optical library. In some implementations, process control logic is configured to computationally combine or otherwise use both information in an optical library and in situ collected measurements for process control decisions. As a more particular example, in some embodiments, an optical library can be used to generate predicted OCD information based on measured in situ reflectance data. Continuing with this particular example, in some embodiments, the predicted OCD information can then be used for process control of the process chamber. As a specific example, the predicted OCD information can be used for endpoint control to determine whether a target etch depth has been reached.

Note that an optical library may be part of an optical library system that uses multiple algorithms. Such an optical library system (which may be referred to as an “AdvancedOptical” system) may use machine learning models and/or non-machine learning algorithms for process control. In some such cases, an optical library which is trained by a library training system using a machine learning model as described herein may be considered an “AdvancedOptical” library.

“Drift” as used herein refers to an increase in an error between predicted ex situ measurements and ground truth ex situ measurements across a plurality of process chambers, such as across a fleet of process chambers. A library training system can monitor metrology data from a fleet of process chambers to detect drift. For example, in some embodiments, the library training system can detect drift in response to determining that an error metric (e.g., a cumulative sum of error) has exceeded a threshold.

“Out of specification” refers to a state in which a library that is being used for process control is generating errors in predicted ex situ measurements which exceed a threshold or otherwise fail to meet a quantitative requirement associated with acceptable predictive capability. Note that out of specification can refer to either a library that is being used and/or a particular process chamber that is using a library. An out of specification determination may be made using two variance-driven metrics, one for the fleet of process chambers using the library, and one for an individual process chamber using the library. In particular, each variance-driven metric may be compared to a threshold to identify the out of specification state.

A “library retraining trigger” as used herein refers to a determination that a library is to be retrained. In some embodiments, the determination can be made based on a detection of drift. Additionally, in some embodiments, the determination can be made based on a determination that a variance of error between predicted ex situ measurements (e.g., where the predicted measurements are calculated using the library and measured in situ measurements) and ground truth ex situ measurements has exceeded a predetermined threshold. In some embodiments, the determination can be made based on a detection that one or more process chambers using a library are out of specification.

### Overview

A library training system as described herein can maintain, evaluate, and/or update, as appropriate, a library to a fleet of process chambers. In some embodiments, the library can be used to take, as an input, an in situ measurement, and generate, as an output, a prediction of an ex situ measurement or other metric that is used for in situ process control by a process chamber during fabrication of a wafer. For example, the in situ measurement can include on-wafer reflectance data that indicates intensities of reflected light at various wavelengths. The reflectance data may be generated by directing light from a light-emitting source in the process chamber onto a substrate that is being processed. In some cases, the in situ reflectance data is time varying; i.e., the reflectance signal is captured at multiple times while the substrate is being processed. Continuing with this example, the reflectance data can be used to generate a prediction of ex situ measurements. The ex situ measurement(s) can indicate one or more characteristics of a post-processed substrate. The characteristics of the post-processed substrate can include one or more geometric characteristics of substrate features (e.g., etch depth, critical dimension, and other aspects of a feature profile). Examples of ex situ measurements include Optical Critical Dimension (OCD) information that indicates geometric information of one or more features of the wafer during fabrication (e.g., an etch depth, etc.), one or more other types of metrology data (e.g., XSEM. CDSEM, TEM, etc.), and the like. Continuing further with this example, the prediction of the ex situ measurement can then be used for process control. As a more particular example, predicted OCD information can be used for endpoint control during etching of a wafer to achieve a target etch depth.

In some embodiments, the library training system can be configured to monitor performance of the fleet of process chambers to determine a time at which an updated library is to be provided to the fleet. For example, the library training system can be configured to trigger retraining of a library based on a calculated error metric(s) that indicates errors in prediction of the ex situ measurements and/or changes in the prediction of the ex situ measurements over time. As a more particular example, the error metric(s) can include increased error in the prediction of the ex situ measurements and/or increased variance in the errors of the prediction of the ex situ measurements across the fleet. Note that, in some embodiments, the library training system can be configured to calculate error by comparing predicted ex situ measurements with actual ex situ measurements that are collected as post-processing metrology data.

In some embodiments, the library training system can be configured to detect an increasing drift in the error with relatively few samples by monitoring changes in prediction error over time. In other words, a fleet-wide prediction error can be considered a process mean, where drifts in the process mean can be controlled by retraining an optical library in response to detection of a drift in the process mean. In some embodiments, drift in the fleet-wide prediction error can be detected using a control chart, such as a cumulative sum (CUSUM) chart, a Shewhart control chart, an Exponentially Weighted Moving Average (EWMA) control chart, a Multiple-Stream Processes (MSP) control chart, etc. By monitoring changes of the errors across the fleet, a drift in the error can be detected when the error is relatively small.

In some embodiments, the library training system can be configured to train an updated library to replace the library that is out of specification. The library training system can then be configured to evaluate the updated library by comparing the updated library with the library that is out of specification such that the updated library is deployed to the fleet if: 1) the updated library is better than the current library that is out of specification; and/or 2) the updated library satisfies absolute performance criteria, such as having an error variance, when evaluated on test data, that is below a threshold. Note that, in some embodiments, the current library and the updated library can both be evaluated on the same test set that neither have been trained with, thereby making both the current library and the updated library blind to the test set.

In some embodiments, if an updated library does not satisfy criteria to be deployed, a second or further iteration of training can be performed to generate a further updated library. In some embodiments, each successive library training iteration can use modified training and test sets. For example, in some embodiments, test sets of successive iterations can be shifted such that libraries are tested on more recent wafer data. As another example, in some embodiments, training sets of successive iterations can be expanded such that libraries are trained on additional training data. By modifying allocation of training sets and test sets over successive library training iterations, an optimal library can be more quickly trained. In particular, by expanding training sets when a library does not satisfy deployment criteria, libraries can be more quickly and efficiently trained.

Note that although the library training system is generally described herein as being configured to provide a library that predicts ex situ measurements (e.g., OCD information) based on in situ optical measurements such as reflectance data, it should be understood that the techniques described herein can be extended for adaptively training other types of machine learning models and/or generating other types of libraries for in situ process control. For example, the techniques can be used to train machine learning models or generate libraries to predict ex situ metrology data using in situ thermal measurements, to predict ex situ metrology data using in situ electrical measurements, etc.

### Library Training System

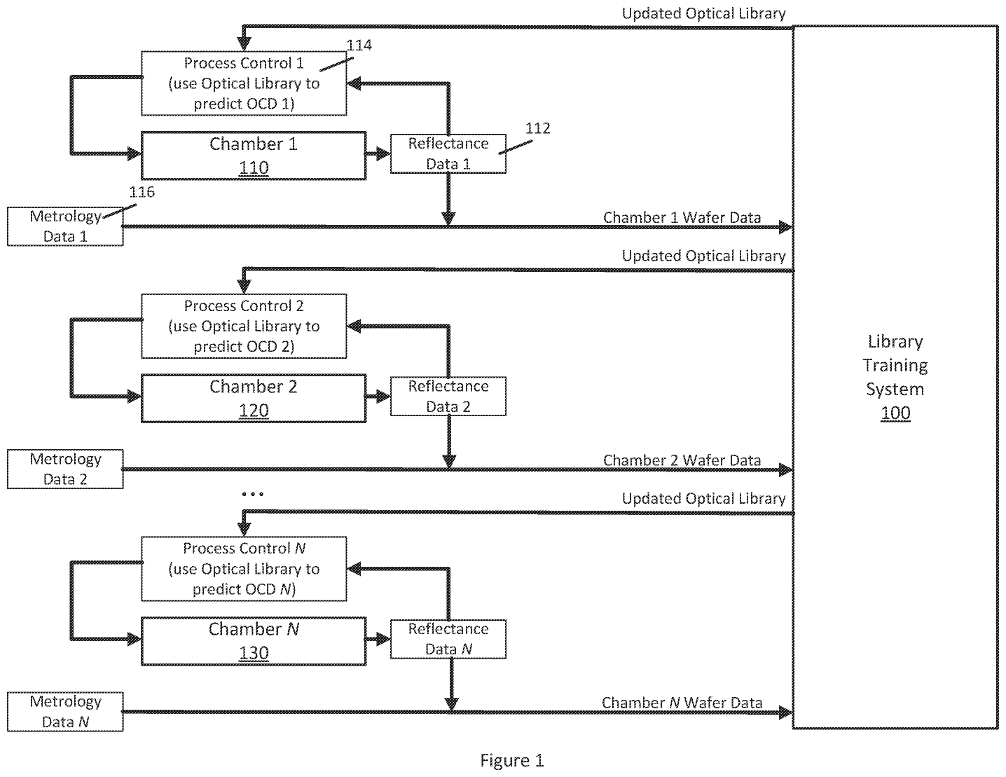

Turning to FIG. 1, a schematic diagram of use of a library training system is shown in accordance with some embodiments of the disclosed subject matter.

As illustrated, in some embodiments, a library training system 100 can be in communication with process chambers included in a fleet of process chambers, such as a process chamber 110, a chamber 120, a chamber 130, etc. shown in FIG. 1. For example, in some embodiments, library training system 100 can be configured to generate optical libraries that can be transmitted and used by the process chambers for process control, as will be described below in more detail. Note that, in some embodiments, each process chamber in the fleet of process chambers may be implementing the same process or recipe for wafer fabrication. In some embodiments, each process chamber in the fleet has the same components and design.

In some embodiments, each process chamber in the fleet of process chambers can collect in situ reflectance data during fabrication of a wafer. For example, as shown in FIG. 1, process chamber 110 can collect reflectance data 112.

Reflectance data 112 can be used by process control logic 114 for process control of process chamber 110 during fabrication of the wafer. For example, process control 114 can modify any suitable parameters to control fabrication of target features of the wafer. As a more particular example, in some embodiments, process control logic 114 can be configured to perform endpoint control by determining whether a target etch depth has been reached during etching of the wafer. As another more particular example, in some embodiments, process control logic 114 can be configured to adjust parameters to control a side wall angle of the wafer.

In some embodiments, process control logic 114 can be configured to use an optical library to calculate predicted Optical Critical Dimension (OCD) information using reflectance data 112. Continuing with this example, the OCD information can be used to predict geometric information associated with a feature of the wafer being fabricated, such as a current etch depth, a current side wall angle, etc.

The process chambers can transmit ex situ metrology data to library training system 100. For example, process chamber 110 can transmit metrology data 116 to library training system 100. In some embodiments, metrology data 116 can be collected for a subset of wafers fabricated by process chamber 110 (e.g., for every tenth wafer, for every twentieth wafer, etc.). In some embodiments, metrology data 116 can include any suitable measurements, such as ground truth OCD information for any particular features of a wafer.

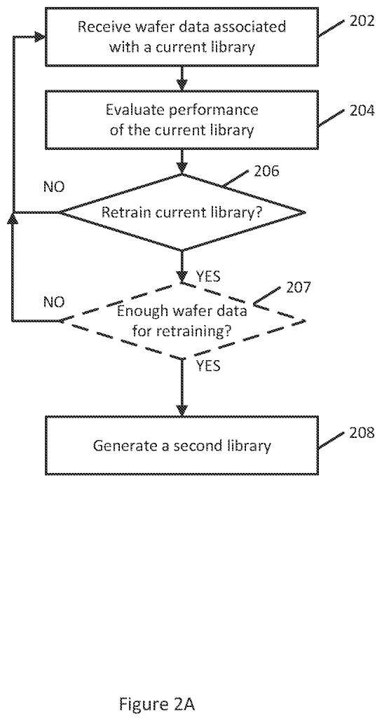

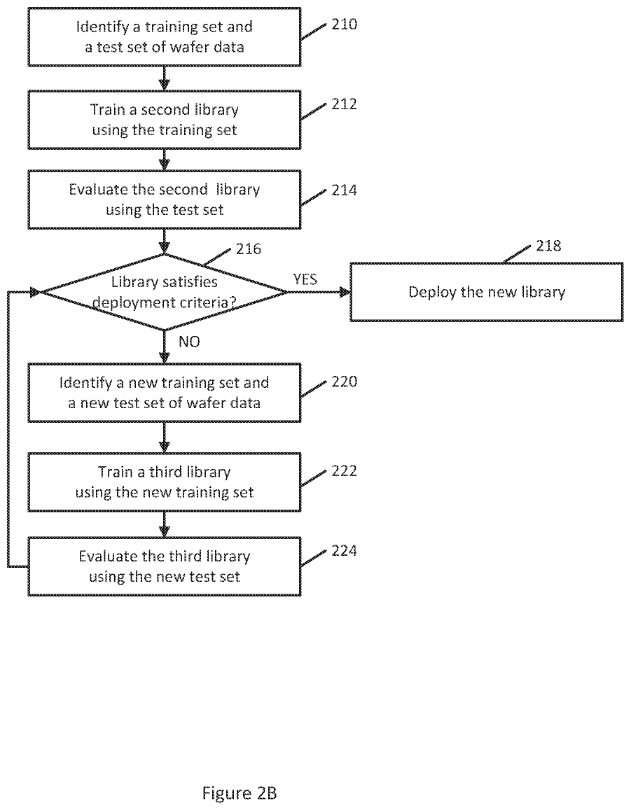

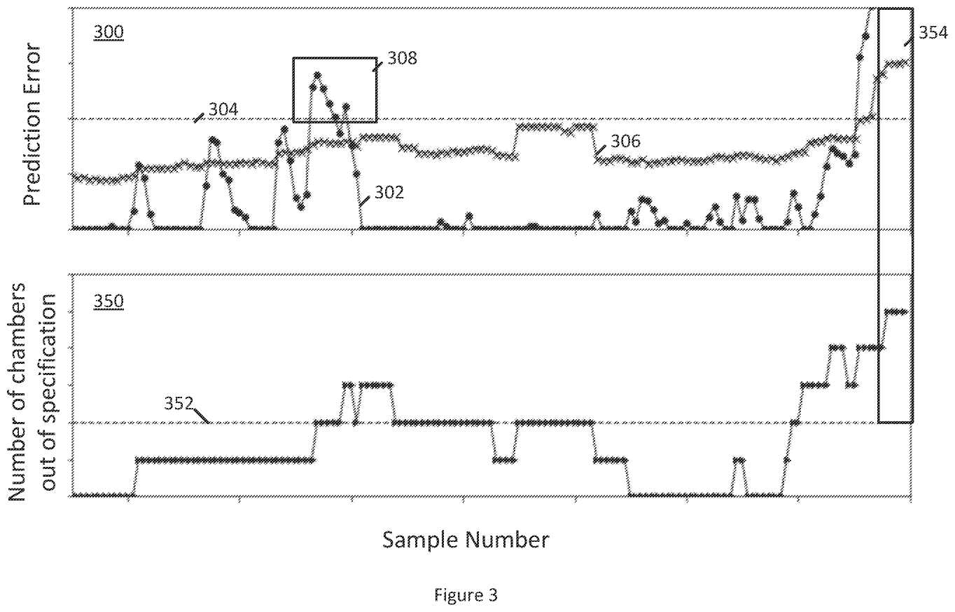

Library training system 100 can be configured to receive metrology data from multiple process chambers in the fleet of process chambers. As described below in more connection with FIGS. 2 and 3, library training system 100 can be configured to determine, based on the received metrology data, whether a current optical library being used by the process chambers for process control is out of specification. For example, library training system 100 can be configured to determine that errors in predicted OCD information have drifted beyond an acceptable threshold based on ground truth OCD information included in received ex situ metrology data.

Library training system 100 can, as described below in more detail in connection with FIG. 2B, be configured to train an updated optical library. Library training system 100 can then be configured to transmit the updated optical library to the process chambers in the fleet of process chambers, as shown in FIG. 1.

Note that, in some embodiments, each process chamber in the fleet of process chambers can use the same optical library that has been trained using metrology data received from multiple process chambers. Continuing further, in some embodiments, each process chamber in the fleet of process chambers can receive the same updated optical library.

Additionally, note that, in some embodiments, one or more process chambers in the fleet of process chambers may not use an optical library provided by library training system 100 for process control. For example, such a chamber may use time of etch data for endpoint control. In some such embodiments, library training system 100 can be configured to determine that an updated optical library is to be provided based on prediction errors by process chambers using the optical library. However, in some embodiments, library training system 100 can be configured to train an updated optical library using metrology data from all process chambers in the fleet of process chambers, including process chambers not using the optical library for process control.

Turning to FIGS. 2A and 2B, example processes for library training are shown in accordance with some embodiments of the disclosed subject matter. The processes can be executed by any suitable device, such as one or more servers of a library training system, as shown in and described above in connection with FIG. 1. Note that all of the blocks shown in FIGS. 2A and 2B need not be performed. Additionally, note that the blocks can be performed in different orders than what is illustrated in FIGS. 2A and 2B.

At 202 of FIG. 2A, wafer data associated with a current library can be received. Such data might be data that can help elucidate the performance of the current library. For example, the wafer data can include ex situ measurements that indicate one or more characteristics of post-processed substrates. As a more particular example, the wafer data can include ex situ metrology data that indicates measured OCD information associated with features of a wafer, such as an etch depth, dimensions of a side wall angle, etc.

In some embodiments, the wafer data can include in situ information used by a process chamber for endpoint control. For example, in some embodiments, the wafer data can include predicted ex situ information such as OCD information calculated using the current library. As another example, in some embodiments, the wafer data can include measured reflectance data from which predicted OCD information can be calculated using the current library.

Note that wafer data can be received from any suitable number of process chambers (e.g., five process chambers, ten process chambers, twenty process chambers, etc.) in a fleet of process chambers. Additionally note that wafer data can be received asynchronously from each of the process chambers in the fleet of process chambers. The wafer data can correspond to multiple wafers (e.g., five wafers, ten wafers, fifty wafers, etc.).

At 204, the performance of the current library can be evaluated. The performance of the current library can be evaluated in any suitable manner. For example, in some embodiments, an error between predicted OCD values calculated using the current library (e.g., based on measured reflectance data) and ground truth OCD values included in or derived from the ex situ metrology data can be calculated. That is, in some embodiments, Error=predicted OCD−ground truth OCD. Note that this error is generally referred to herein as “offline error.”

In some embodiments, an “online error” can be calculated as Error=Ground Truth OCD−Target+Offset, where Target indicates a target value (e.g., a target etch depth, etc.) each process chamber is to achieve for a fabricated wafer, and where the Offset parameter encapsulates differences between different process chambers in the fleet. Note that, the online error can implicitly indicate in situ information, such as predicted OCD based on in situ reflectance measurements. Additionally, in some embodiments, in an instance in which an online error is calculated, the wafer data received at block 202 need not include in situ information, such as in situ reflectance measurements, predicted OCD information, etc.

In some embodiments, error values can be analyzed in any suitable manner. For example, error values aggregated across the fleet of process chambers using the optical library can be analyzed. Continuing with this example, a fleet-wide error metric can be maintained and updated over time (i.e., as additional wafer data is received). Examples of methods for maintaining and updating fleet-wide error metrics include a CUSUM control chart, a Shewhart control chart, an EWMA control chart, an MSP control chart, monitoring a fleet-wide error to detect a change in the fleet-wide error that exceeds a threshold over a particular time period, etc. Note that use of a CUSUM is described below in more detail in connection with FIG. 3.

Turning to FIG. 3, an example chart 300 for analyzing error values is shown in accordance with some embodiments of the disclosed subject matter.

In some embodiments, a cumulative sum (CUSUM) of the error values 302 can be calculated. Note that CUSUM of the error values 302 that is shown in FIG. 3 and described below in more detail is for positive error values (e.g., when predicted OCD>ground truth OCD for offline error and/or when ground truth OCD>target for online error). In some embodiments, although not shown in FIG. 3, a corresponding CUSUM for negative error values can be calculated and plotted in chart 300.

In some embodiments, CUSUM of the error values 302 can be calculated for positive error values as CUSUM_POS(i)=Max[0, CUSUM_POS(i−1)+Error(i)−k], where i is the wafer data sample number, Error(i) is the error for the i^{th} sample, and k is a parameter that indicates allowable slack in the error. In some embodiments, k can be set to any value, such as a desired standard deviation of error value distributions. Note that CUSUM_POS(0) can be set to have a value of 0.

Note that a CUSUM for negative error values (not shown in FIG. 3) can be calculated as CUSUM_NEG(i)=Max[0, CUSUM_NEG(i−1)−Error(i)−k]. The CUSUM for negative error values can be updated with negative error values, i.e., when predicted OCD<actual OCD for offline error or when ground truth OCD<target for online error. Note that CUSUM_NEG(0) can be set to have a value of 0.

An example of CUSUM for positive error values is given hereinbelow, in which k is set to 0.7. If Error(1) is calculated as 1.1 (and therefore, is a positive error value), CUSUM_POS(1)=Max[0, CUSUM_POS(0)+1.1−0.7]=Max[0, 0.4]=0.4. Similarly, CUSUM_NEG(1)=Max[0, CUSUM_NEG(0)−1.1−0.7]=Max[0, −1.8]=0.

Continuing further with this example, if Error(2) is calculated as −0.9 (and therefore, is a negative error value), the CUSUM for the positive error values (i.e., CUSUM_POS) will be updated to 0. That is, CUSUM_POS(2)=MAX[0, CUSUM_POS(1)+(−0.9)−0.7]=MAX[0, −1.2]=0. The CUSUM for negative error values will be updated to 0.2. That is, CUSUM_NEG(2)=MAX[0, CUSUM_NEG(1)−(−0.9)−0.7]=MAX[0, 0.2]=0.2.

Continuing still further with this example, if Error(3) is calculated as 0.2, CUSUM_POS(3)=MAX[0, CUSUM_POS(2)+0.2−0.7]=MAX[0, −0.5]=0. Similarly, CUSUM_NEG(3)=MAX[0, CUSUM_NEG(2)−(0.2)−0.7]=MAX[0, −0.7]=0.

Note that, as in the example given above, and as shown in CUSUM of the error values 302, CUSUM values need not be monotonic. Additionally, as shown in the example calculations above, CUSUM_POS and CUSUM_NEG will have values greater than or equal to 0.

In some embodiments, CUSUM of the error values 302 can be compared to a control threshold 304 to evaluate the performance of the current library. For example, drift in the error values can be considered detected in response to determining that CUSUM of the error values 302 exceeds control threshold 304. Control threshold 304 can be set to any suitable value. For example, in some embodiments, control threshold 304 can be set to 3 times a desired Standard Deviation (STD) of a distribution of error values across the fleet of process chambers, referred to herein as 3σ. Note that although 3σ is generally used here, in some embodiments, any suitable value can be used for a control threshold, such as 2σ, 4σ, and/or any other suitable value.

Note that, although not shown in FIG. 3, drift can be detected in response to determining that a CUSUM of negative error values is less than a negative control threshold. For example, drift can be detected in an instance in which the negative control threshold is −2.2, and in which the CUSUM of negative error values reaches −2.5.

In some embodiments, a variance of the error values 306 can be calculated. Note that variance of the error values 306 can be the variance in error values across all process chambers of the fleet. In particular, note that the variance in error values can be calculated using values across all process chambers, regardless of how many values each chamber contributes. In some embodiments, the error values can be mean-centered prior to calculating variance of the error values 306. In some such embodiments, variance of the error values 306 can represent a variance of the distribution of the error values while effectively disregarding the mean of the error values. Conversely, the CUSUM of the error values can effectively represent changes in the mean of the error values across the process chambers.

In some embodiments, variance of the error values 306 can be compared to control threshold 304 to evaluate the performance of the current library. For example, an increase in error variance across the process chambers in the fleet can be detected in response to determining that variance of the error values 306 has exceeded control threshold 304.

Referring back to FIG. 2A, at 206, a determination of whether to retrain the current library can be made. In some embodiments, the determination can be made based on whether the performance of the current library satisfies criteria for retraining. For example, the criteria can include whether drift in an error of the current library is detected. As a more particular example, drift in the error of the current library can be detected based on a current value of a control chart (e.g., a CUSUM control chart, a Shewhart control chart, an EWMA control chart, an MSP control chart, etc.) indicates drift in the prediction error. As another more particular example, drift in the error of the current library can be detected based on an error of the library jumping by more than a threshold amount (e.g., more than 0.2, more than 0.5, etc.) over a particular time window or over a particular number of samples of wafer data. Note that a drift in prediction error may be due to the entire fleet of process chambers, or to a subset of the process chambers.

As a specific example, drift can be detected when a CUSUM of error values exceeds a control threshold. For example, referring to FIG. 3, drift can be detected based on CUSUM values 308 which are above control threshold 304. Note that drift can be detected based on a CUSUM of negative error values, which are not shown in FIG. 3. For example, drift can be detected when the CUSUM of negative error values exceeds control threshold 304.

As another example, in some embodiments, the criteria can include whether the variance of the mean-centered errors across the process chambers in the fleet exceeds a control threshold. Note that, in some embodiments, a control threshold for detecting drift (e.g., using CUSUM of error values) and a control threshold used in connection with variance of mean-centered errors can be the same control threshold, as shown in and described above in connection with FIG. 3. Conversely, in some embodiments, two different control thresholds can be used for drift in error values and for variance in error values.

In some embodiments, the criteria can include whether a number of process chambers in the fleet that are out of specification exceeds a chamber threshold. An individual process chamber can be determined to be out of specification when a prediction error associated with the process chamber exceeds an error threshold. Turning again to FIG. 3, graph 350 shows the number of process chambers in the fleet out of specification as a function of wafer sample number. Note that graph 350 shows chamber threshold 352. In some embodiments, chamber threshold 352 can indicate a maximum number of process chambers in the fleet that can be out of specification, such as two chambers, three chambers, etc. Additionally or alternatively, in some embodiments, chamber threshold 352 can indicate a maximum percentage of process chamber in the fleet that can be out of specification, such as 5%, 10%, etc.

Referring back to FIG. 2A, in some embodiments, a determination to retrain the current library can be made when any suitable combination of criteria are met from the group of: 1) a CUSUM of error values exceeds a control threshold: 2) a variance of mean-centered errors exceeds the control threshold; and 3) a number of process chambers out of specification exceeds a chamber threshold. Note that, in some embodiments, a control threshold and/or a chamber threshold can be set by any suitable entity, such as an operator of the fleet of process chambers.

For example, referring to FIG. 3, a determination to retrain the current library can be made based on wafer samples 354, for which all three retraining criteria are satisfied. Alternatively, in some embodiments, a determination to retrain the current library can be made in response to any subset of the criteria being satisfied.

Referring back to FIG. 2A, if, at 206, it is determined that the current library is not to be retrained (“no” at 206), the process can loop back to 202 and receive additional wafer data associated with the current library.

Conversely, if, at 206, it is determined that the current library is to be retrained (“yes” at 206), a determination of whether there is enough wafer data for retraining the current library can be made at 207.

The determination of whether there is enough wafer data for retraining the current library can be made based on a determination of whether a number of currently available wafer samples exceeds a training set threshold. The training set threshold can be any suitable number of training samples, such as fifty samples, one hundred samples, two hundred samples, etc.

If, at 207, it is determined that there is not enough wafer data for retraining the current library (“no” at 207), the process can loop back to 202 and receive additional wafer data associated with the current library. Note that, in some embodiments, blocks 204 and 206 can be omitted because the current library was previously evaluated and determined to be out of specification.

Conversely, if, at 207, it is determined that there is enough wafer data for retraining (“yes” at 207), a second library can be generated at 208. The second library can be generated by training a second library using ex situ data and in situ measurements. Note that detailed techniques for generating a second library are shown in and described below in connection with FIG. 2B.

Turning to FIG. 2B, a flowchart that illustrates a process for library training is shown in accordance with some embodiments of the disclosed subject matter.

At 210, a test set and a training set of wafer data can be identified.

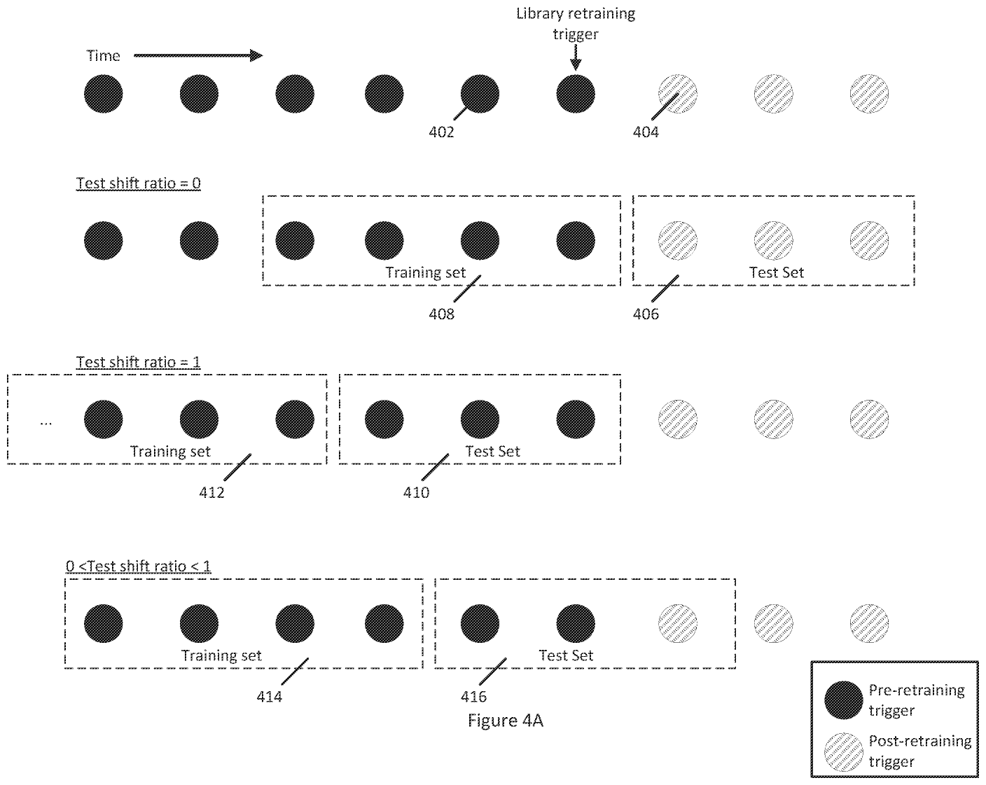

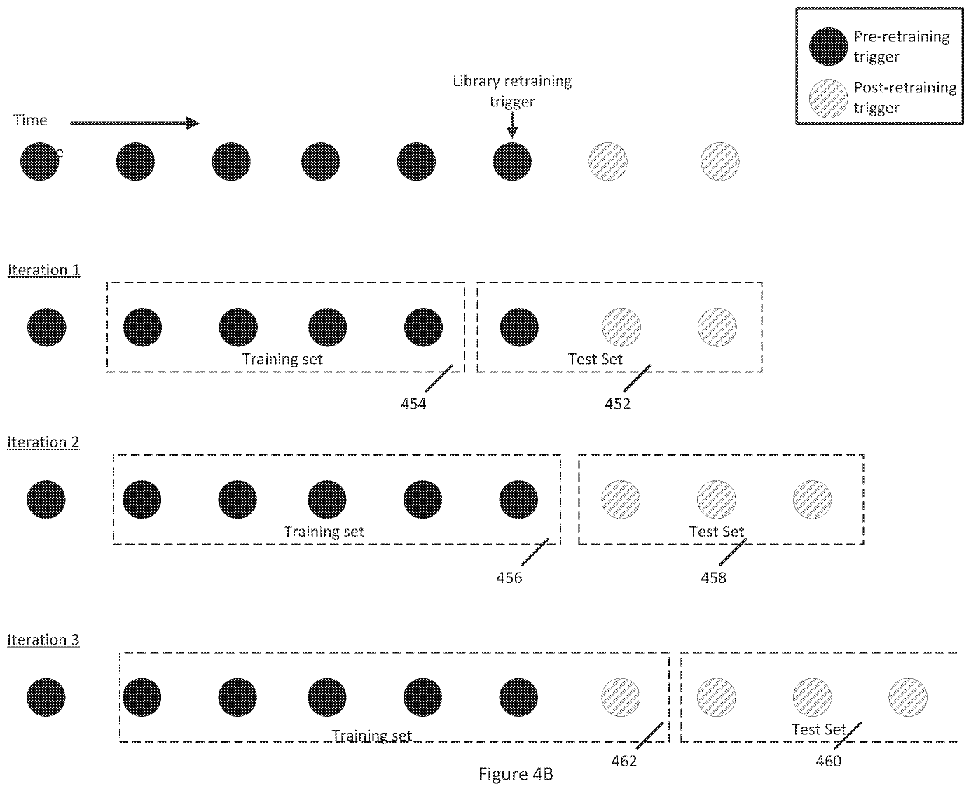

The training set and the test set of wafer data can be identified in any suitable manner. Turning to FIG. 4A, a schematic diagram that illustrates various techniques for identifying a training set and a test set is shown in accordance with some embodiments of the disclosed subject matter.

Each circle shown in FIG. 4A represents wafer data received by the library training system. Note that each circle can represent any suitable number of wafer data samples (e.g., ten samples, twenty samples, fifty samples, etc.). Black circles represent wafer data received prior to and including the sample at which library retraining was triggered (e.g., wafer data 402), and hashed circles represent wafer data received after the library retraining trigger (e.g., wafer data 404).

In some embodiments, each wafer data sample can include in situ data, such as in situ reflectance data measured during fabrication of a wafer. In some embodiments, the in situ data can be data measured during fabrication of a wafer that is used to generate predicted OCD information during fabrication of the wafer (e.g., for process control, for endpoint control, etc.). Additionally, in some embodiments, each wafer data sample can include ex situ data, such as metrology data collected post-fabrication for a wafer. In some embodiments, the metrology data can include measured OCD information, such as measured etch depth information.

In some embodiments, each sample in a training set and/or in a test set can include both in situ data and ex situ data. For example, in some embodiments, predicted OCD information can be an input value of a training sample or of a test sample, and ex situ data, such as measured OCD information, can be a target output of the training sample or of the test sample.

In some embodiments, the training set and the test set can be allocated such that the test set includes wafer data samples received after the library retraining trigger (e.g., test set 406), and the training set includes wafer data samples received prior to and including the library retraining trigger (e.g., training set 408). This is generally referred to herein as a test shift ratio of 0, as shown in FIG. 4A.

In some embodiments, the training set and the test set can be allocated such that both the test set and the training set include wafer data samples received prior to and including the sample that triggered library retraining, such as test set 410 and training set 412. This is generally referred to herein as a test shift ratio of 1.

In some embodiments, the training set and the test set can be allocated such that the training set includes wafer data samples received prior to the sample that triggered library retraining (e.g., training set 414), and the test set includes wafer data samples both prior to and including the sample that triggered library retraining, as well as wafer data samples received after the sample that triggered library retraining (e.g., test set 416). This is generally referred to herein as a test shift ratio between 0 and 1, where the value of the test shift ratio can be any fractional value between 0 and 1.

Note that different values of the test shift ratio can vary a proportion of wafer data samples included in the test set that are received after the library retraining trigger. For example, test shift ratio values that are relatively closer to 0 can include more wafer data samples received after the sample that triggered library retraining relative to a test shift ratio closer to 1.

Additionally, note that the sizes of the training set and the test set shown in FIG. 4A, as well as the size of the training set relative to the size of the test set, are merely exemplary. In some embodiments, the training set and the test set can each have any suitable number of wafer data training samples.

Referring back to FIG. 2B, at 212, a second library can be trained using the training set. For example, in some embodiments, a machine learning model can be used to learn coefficients that predict ex situ data from in situ data. As a more particular example, the second library can include coefficients that predict OCD information based on measured reflectance data.

Note that, in some embodiments, the second library can be validated using a validation set. In some embodiments, the validation set can be constructed as a subset of the training set prior to training the second library using a remaining portion of the training set.

At 214, the second library can be evaluated using the test set.

In some embodiments, evaluating the second library can include calculating a set of prediction errors for the second library. For example, for each sample in the test set, a predicted OCD value can be calculated using the second library and the input values of the sample. Continuing with this example, a sample error can be calculated as the difference between the predicted OCD information and the ground truth OCD information. The set of prediction errors can therefore indicate prediction errors for each test set sample.

Note that, in some embodiments, a set of prediction errors can similarly be generated for the current library when evaluated using the test set. That is, in some embodiments, the current library and the second library can each be evaluated using the same test set. Moreover, in some embodiments, because neither the current library nor the second library were trained using samples included in the test set, both the current library and the second library can be considered blind to the test set.

In some embodiments, the second library can be evaluated by calculating any suitable metrics associated with the set of prediction errors associated with the test set. For example, the metrics can include a standard deviation (STD) of the set of prediction errors, a 3σ of the prediction errors, a variance of the prediction errors, a mean of the prediction errors, and/or any other suitable metrics. Similarly, in some embodiments, corresponding metrics can be calculated for the set of prediction errors for the current library.

At 216, a determination of whether the second library satisfies deployment criteria can be made.

For example, in some embodiments, the criteria can include whether a performance of the second library when evaluated on the test set is better than the performance of the current library when evaluated on the test set.

In some embodiments, performance of each of the second library and the current library can be indicated with any suitable metric, such as 3σ of the set of prediction errors. For example, in an instance in which the set of prediction errors for the second library is [0.2, 2.3, 0.5, 0.7, 0.8] and in which the set of prediction errors for the current library is [0.6, 0.9, 4.3, 0.2, 3.4], 3σ of the set of prediction errors for the second library is 2.19 and 3σ of the set of prediction errors for the current library is 4.92.

In some embodiments, the second library can be considered an improvement over the current library if an improvement of the second library over the current library with respect to the performance metric exceeds an improvement threshold. For example, the improvement threshold can be 20%, 30%, and/or any other suitable improvement threshold. Continuing with the example above, the improvement of the second library relative to the current library with respect to the test set and when using 3σ as the performance metric is 55%. In an instance in which the improvement threshold is 20%, the second library can be considered better than the current library.

As another example, in some embodiments, the criteria can include an absolute performance of the second library when evaluated on the test set. As a more particular example, in some embodiments, the criteria can include whether the performance of the second library when evaluated on the test set is below an error threshold. As a specific example, in an instance in which the performance metric is 3σ of the set of prediction errors, the error threshold can be a desired 3σ value. Continuing with this specific example, referring to the example given above, in an instance in which the 3σ value of the set of prediction errors for the second library is 2.19, and in which the error threshold is 2.2, the performance of the second library when evaluated on the test set is below the error threshold, and therefore, can be deemed to satisfy absolute performance criteria.

In some embodiments, the deployment criteria can be satisfied based on any suitable combination of the criteria being met. For example, in some embodiments, the deployment criteria can be satisfied when both: 1) the second library is better than the current library with respect to evaluation on the test set; and 2) performance of the second library on the test set is below an error threshold. Note that improvement of the second library with respect to the current library is generally referred to herein as the second library being “qualified.” Additionally, note that performance of the second library being below the error threshold is generally referred to herein as the second library being “optimal.”

If, at 216, it is determined that the second library satisfies the deployment criteria (“yes” at 216), the second library can be deployed at 218. For example, the second library can be transmitted to each of the process chambers in the fleet. In some embodiments, the process chambers can then each replace the current library with the second library for use in process control.

Note that, in some embodiments, the second library can be deployed to the process chambers in the fleet if the second library is determined to be qualified but not optimal. That is, the second library can be deployed if the second library is an improvement over the current library even if the performance of the second library is not below an error threshold. In some such embodiments, the second library can be deployed, and blocks 220-224, described below, can be executed to train a third library. Additionally, in some such embodiments, the second library can be transmitted to the process chambers in the fleet in connection with a warning message that indicates that the second library is not an optimal library.

If, at 216, it is determined that the second library does not satisfy the deployment criteria (“no” at 216), a new training set and a new test set of wafer data can be identified to train a third library at 220. Note that training of the second library (e.g., as described above in connection with blocks 210-214) is referred to herein as Iteration 1, and training of the second library (e.g., as described below in connection with blocks 220-224) is referred to herein as Iteration 2.

Turning to FIG. 4B, an example schematic diagram for identifying new training sets and new tests of wafer data is shown in accordance with some embodiments of the disclosed subject matter.

Test set 452 and training set 454 show test and training sets used in connection with training and evaluation of the second library (i.e. Iteration 1). Note that although test set 452 and training set 454 are shown using a test shift ratio between 0 and 1 (e.g., as described above in connection with FIG. 4A), any suitable test shift ratio can be used for training and evaluation of the second library in Iteration 1.

During Iteration 2 (i.e., training and evaluation of the third library, as shown in and described above in connection with blocks 220-224 of FIG. 2B), training set 456 can be used to train the third library, and test set 458 can be used for evaluation. Note that test set 458 can be used for evaluation of the third library, as well as for evaluation of the second library when compared to the third library (e.g., to determine if the third library is an improvement over the second library).

In some embodiments, test set 458 can be the same size as test set 452. However, in some embodiments, test set 458 can include wafer data samples that are more recent than those included in test set 452, as shown in FIG. 4B.

In some embodiments, training set 456 can have a size that is larger than training set 454, as shown in FIG. 4B. In some embodiments, training sets for each successive iteration can be increased by a fixed number of wafer data samples (e.g., data from one hundred wafers, data from two hundred wafers, etc.). For example, in an instance in which each circle shown in FIG. 4B represents 50 wafer data samples, training set 456 can include an additional 50 wafer data samples relative to training set 454. Additionally, in some embodiments, training set 456 of Iteration 2 can be shifted to include wafer data samples that are more recent than those included in training set 454 of Iteration 1.

Test set 460 and training set 462 show a test set and a training set, respectively for an Iteration 3 of library training, for example, in an instance in which the library generated during Iteration 2 does not satisfy deployment criteria.

As illustrated, in some embodiments, test set 460 can be the same size as test set 458 and/or test set 452. Additionally, as illustrated, in some embodiments, test set 460 can be shifted to include wafer data samples that were received more recently than those included in test set 458 and/or test set 452.

In some embodiments, training set 462 can be larger than training set 456 and training set 454. For example, as shown, training set 462 can be increased in size relative to training set 456 to include an additional fixed number of wafer data samples. As a more particular example, in an instance in which each circle shown in FIG. 4B represents 50 wafer data samples, training set 462 can have 50 additional wafer data samples relative to training set 456 of Iteration 2, and 100 additional wafer data samples relative to training set 454 of Iteration 1.

Note that an increase in size of a training set relative to a training set of a previous iteration can be achieved by including more recently received wafer data samples (e.g., as shown with respect to training sets 456 and 462) and/or by including older wafer data samples. For example, in an instance in which there are an insufficient number of wafer data samples to both shift the test set and expand the training set with newly received wafer data samples, the training set can be expanded by including older wafer data samples.

Referring back to FIG. 2B, at 222, a third library can be trained using the new training set. Note that this is Iteration 2, as shown in and described above in connection with FIG. 4B.

Similarly to what is described above in connection with block 212, the third library can be trained. For example, a machine learning model can be used to learn coefficients that predict an ex situ value (e.g., ex situ OCD information indicated in metrology data) based on in situ measurements, such as in situ reflectance measurements.

In some embodiments, the third library can be validated using a validation set that is a portion of the training set. In some such embodiments, the validation set can be constructed prior to training of the third library, and the third library can be trained using the remaining portion of the training set that does not include the validation set.

At 224, the third library can be evaluated using the new test set. The third library can be evaluated using the techniques described above in connection with block 214. Note that performance of the third library when evaluated using the new test set can be compared to performance of the current library when evaluated using the new test set.

The process can then loop back to block 216 and can determine whether the third library satisfies the deployment criteria.

Note that, in some embodiments, blocks 216-224 can be repeated until a library that is deemed optimal (i.e., that satisfies absolute performance criteria) has been trained.

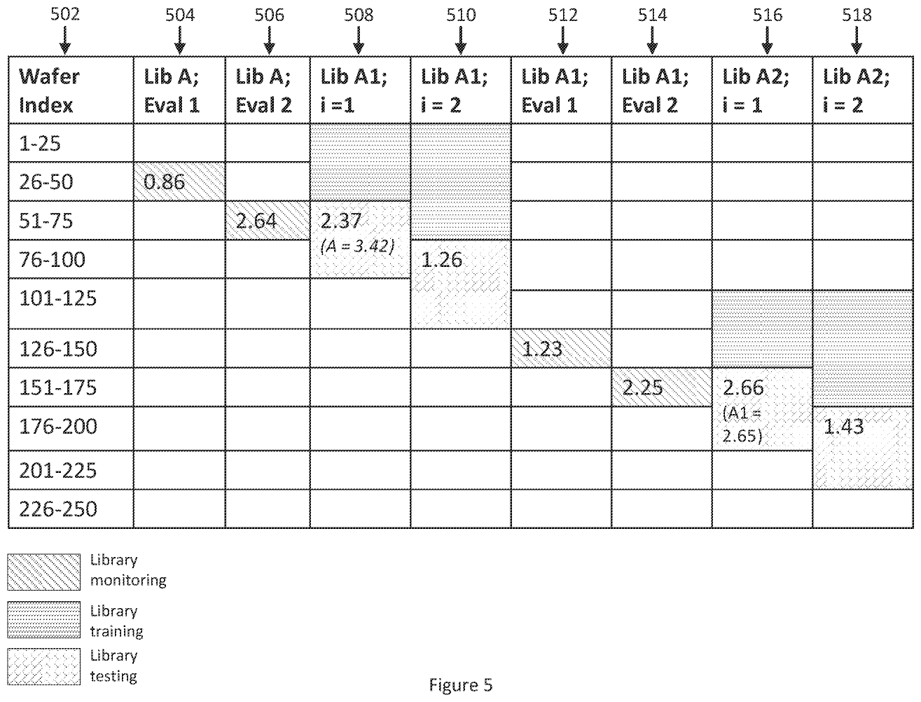

Turning to FIG. 5, an example table of metrics of libraries evaluated and/or trained by a library training system is shown in accordance with some embodiments of the disclosed subject matter.

Column 502 shows the wafer data index of wafers used for evaluating and/or training a particular library. Note that wafer data indices are binned in groups of 25 to avoid over-complicating the table. Additionally, note that although wafer data indices are binned in groups of 25, in some embodiments, an evaluation set, a training set, and/or a testing set can include any suitable number of wafer data samples (e.g., fifty, one hundred, two hundred, etc.) other than what is shown.

Column 504 shows a performance metric of a Library A at a first time of evaluation. As shown, Library A is evaluated using wafers 26-50. Note that the performance metric shown in FIG. 5 is 3σ of the predictions errors when evaluating the library on the indicated samples. As described above, the prediction error for each wafer is the difference between the ground truth OCD information and the predicted OCD information, where the predicted OCD information is predicted using Library A and in situ measurements (e.g., reflectance data) and where the ground truth OCD information is ex situ metrology data.

In some embodiments, in response to determining that the performance metric satisfies performance criteria, such as that the 3σ value is below a threshold, Library A can be evaluated again, as shown in column 506. Note that the threshold can be a desired 3σ value. Example threshold values are 1.8, 2.2, 2.5, etc.

In the example shown in FIG. 5, because the 3σ value for Library A when evaluated using wafers 26-50 is below a threshold of 2.2, Library A is evaluated again using wafers 51-75, as shown in column 506.

Note that the 3σ value for Library A when evaluated using wafers 51-75 is above the threshold of 2.2. Accordingly, training of Library A1 is initiated, as shown in column 508. As shown in column 508, Library A1 is trained using wafers 1-50, and is tested using wafers 51-75. The 3σ value for Library A1 when tested using wafers 51-75 is 2.37. As shown in column 508, Library A is also evaluated using wafers 51-75, and the corresponding 3a value for Library A is 3.42.

In the example shown in FIG. 5, Library A1 is an improvement over Library A, because the 3σ value for Library A1 (2.37) is less than the 3σ value for Library A (3.42). Additionally, in an instance in which the improvement threshold is 20%, Library A1 can be deemed qualified, because the performance improvement of Library A1 relative to Library A is more than 20%. However, note that the 3σ value for Library A1 when evaluated on the test set of wafers 51-100 is more than the desired 3a threshold of 2.2. Accordingly, Library A1, after the first iteration, is not deemed optimal.

Because Library A1, after the first iteration, is not deemed optimal, a second iteration of training is initiated, as shown in column 510. As illustrated, the second iteration of Library A1 is trained using an expanded training set of wafers 1-75. The second iteration of Library A1 is evaluated using a test set of wafers 76-125. As illustrated, the 3σ value for the second iteration of Library A1 is 1.26, which is less than the desired 3a threshold of 2.2. Accordingly, the second iteration of Library A1 is deemed optimal, and the second iteration of Library A1 is deployed to the process chambers in the fleet.

The second iteration of Library A1 is then evaluated, as shown in column 512. For example, the performance of the second iteration of Library A1 is evaluated using wafers 126-150. As illustrated, the 3σ value when Library A1 is evaluated using wafers 126-150 is 1.23. Because the 3σ value is below the desired 3a threshold of 2.2, library retraining is not initiated.

As shown in column 514, the second iteration of Library A1 is evaluated on wafers 151-175. The 3σ value for wafers 151-175 is 2.25. Because the 3σ value exceeds the desired 3σ threshold of 2.2, library retraining is initiated, as shown in column 516.

A first iteration of Library A2 is trained using a training set of wafers 101-150 as shown in column 516. Library A2 is then tested using wafers 151-200, which provides a 3σ value of 2.66. Note that the second iteration of Library A1 is also tested using wafers 151-200, which provides a 3σ value of 2.65. Note that the first iteration of Library A2 is not better than the second iteration of Library A1, because the 3σ value of the first iteration of Library A2 (2.66) is greater than the 3σ value of the second iteration of Library A1 (2.65). Accordingly, the first iteration of Library A2 is neither qualified nor optimal.

A second iteration of Library A2 is therefore trained, as shown in column 518. As illustrated, the second iteration of Library A2 is trained using an expanded training set that includes wafers 101-175. The second iteration of Library A2 is then tested using wafers 176-225, which provides a 3σ value of 1.43. The second iteration of Library A2 when tested using wafers 176-225 is compared to performance of Library A1 on the same test set. Because the 3σ value of the second iteration of Library A2 is less than the desired 3a threshold of 2.2, and because the 3σ value of the second iteration of Library A2 is an improvement over Library A1, the second iteration of Library A2 is deemed optimal, and is deployed to the process chambers in the fleet.

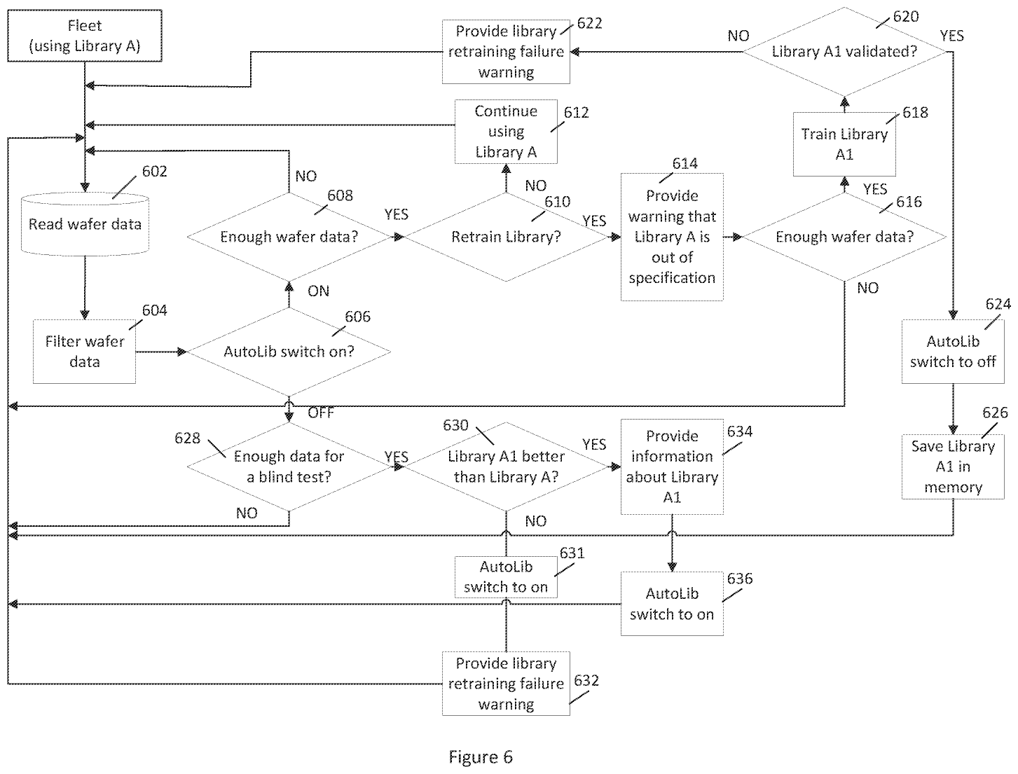

Turning to FIG. 6, an example flowchart for library retraining that can be implemented by a library training system is shown in accordance with some embodiments of the disclosed subject matter.

At 602, the library training system can be configured to read wafer data, for example, from a database that stores wafer data. In some embodiments, the wafer data can include ex situ metrology data. In some embodiments, the wafer data can additionally include any suitable in situ measurements, such as reflectance measurements collected during operation of process chambers in a fleet.

Note that, at 602, the database can include data collected from process chambers in a fleet of process chambers that are currently using Library A that was, for example, previously provided by the library training system.

At 604, the library training system can be configured to filter the wafer data. In filtering the library data, the library training system can be configured to remove invalid data, such as missing values, Not a Number (NaN) values, etc.

At 606, the library training system can be configured to determine whether an AutoLib switch is “on” or “off.” Note that the AutoLib switch can indicate whether or not library retraining has previously been triggered. In particular, if the AutoLib switch is “on” at 606, the library training system can be configured to be in a monitoring mode where library retraining has not yet been triggered. Conversely, if the AutoLib switch is “off” at 606, the library training system can have generated an updated library (i.e., Library A1, as discussed below), and is in a testing mode to determine if Library A1 is to be deployed.

If, at 606, the AutoLib switch is on, the library training system can be configured to determine if there is currently enough wafer data to evaluate deployed Library A at 608.

If, at 608, the library training system determines that there is not enough wafer data (“no” at 608), the library training system can wait to receive additional wafer data.

Conversely, if, at 608, the library training system determines that there is enough wafer data, the library training system can be configured to determine whether to retrain Library A at 610. In some embodiments, the determination of whether to retrain Library A can be based on an evaluation of a performance of Library A in predicting ex situ metrology measurements, as described above in connection with blocks 204 and 206 of FIG. 2A.

If, at 610, the library training system determines that the library is not to be retrained (“no” at 610), Library A can continue being used by the fleet of process chambers at 612.

Conversely, if, at 610, the library training system determines that the library is to be retrained (“yes” at 610), the library training system can be configured to provide a warning that Library A is out of specification to the fleet of process chambers at 614. Note that, in some embodiments, block 614 can be omitted.

The library training system can be configured to determine whether there is enough wafer data for retraining the library at 616.

If, at 616, the library training system determines that there is not enough wafer data for retraining the library (“no” at 616), the library training system can wait to receive additional wafer data.

If, at 616, the library training system determines that there is enough wafer data for retraining the library (“yes” at 616), the library training system can be configured to train a new library, Library A1, at 618. Note that techniques for training Library A1 are described above in more detail in connection with blocks 210 and 212 of FIG. 2B.

The library training system can then be configured to determine whether Library A1 is validated at 620. For example, as described above in connection with FIG. 2B, in some embodiments, Library A1 can be validated using a validation set.

If, at 620, the library training system determines that Library A1 is not validated (“no” at 620), the library training system can be configured to provide a library retraining failure warning at 622. For example, the library training system can be configured to transmit a message to the fleet of process chambers that indicates that a newly trained library is not yet available.

Conversely, if, at 620, the library training system determines that Library A1 is validated (“yes” at 620), the library training system can switch the AutoLib switch to off at 624. That is, by switching the AutoLib switch to off, the library training system can be switched to a mode that indicates that Library A1 has been trained (and therefore, a mode in which retraining will not be triggered again during testing of Library A1).

At 626, the library training system can be configured to save Library A1 in memory (e.g., in a memory of a server corresponding to the library training system) and can wait to receive additional wafer data for testing Library A1.

Referring back to block 606, the library training system can be configured to determine that the AutoLib switch is now off. The library training system can then be configured to determine, at 628, whether there is enough wafer data for a blind test of Library A1 and a blind test of Library A.

Note that, in some embodiments, whether or not there is enough wafer data for a blind test set can depend on a value of the test shift ratio, as described above in connection with FIG. 2B and FIG. 4A. For example, in an instance in which the test shift ratio is 0 and therefore, the test set only includes wafer data samples received after the sample that triggered library retraining, the library training system may need to wait for additional wafer data to perform the blind test. Conversely, in an instance in which the test shift ratio is 1, and therefore, the test set only includes wafer data samples received prior to the sample that triggered library retraining, the library training system may have already received enough wafer data to perform the blind test.

If, at 628, the library training system determines that there is not enough wafer data for a blind test (“no” at 628), the library training system can be configured to wait to receive additional wafer data to construct a test set.

If, at 628, the library training system determines that there is enough wafer data for a blind test (“yes” at 628), the library training system can be configured to determine whether Library A1 is better than Library A at 630. Note that blocks 214 and 216 of FIG. 2B describe detailed techniques for evaluating Library A1 and Library A using a test set.

If, at 630, the library training system determines that Library A1 is not better than Library A (“no” at 630), the library training system can be configured to switch the AutoLib switch to “on,” at 631, thereby placing the library training system in a monitoring and/or retraining mode.

The library training system can then be configured to provide a library retraining failure warning at 632. The library training system can then be configured to wait for additional wafer data and can be configured to retrain a second iteration of the new library (i.e., a Library A2, not shown in FIG. 6).

Conversely, if, at 630, the library training system determines that Library A1 is better than Library A (“yes” at 630), the library training system can be configured to provide information about Library A1 at 634. For example, as described above in connection with block 218 of FIG. 2B, the library training system can be configured to deploy Library A1 to the fleet of process chambers.

At 636, the library training system can be configured to switch the AutoLib switch to “on,” thereby placing the library training system in a mode to monitor newly deployed Library A1.

### Applications

In some embodiments, the library training system can be configured to provide a trained library to a fleet of process chambers for use in process control. For example, a provided library can be used to predict ex situ measurements using in situ measurements during wafer fabrication. As a more particular example, a provided library can be used to predict OCD information using in situ measurements such as reflectance data to control an etch depth during an etching process.

In some embodiments, the library training system can be configured to determine when a provided library is out of specification. That is, the library training system can be configured to determine when errors of predicted ex situ measurements have drifted beyond an acceptable limit. By monitoring performance of the library on multiple process chambers (e.g., all process chambers in the fleet that are using the library), the library training system can be configured to detect increasing variance in performance among the process chambers. Moreover, by maintaining a cumulative error sum, a small drift in error can be detected with relatively little data.

It can be difficult to determine an optimal amount of training and test data when training a library. For example, using too much training data can cause library training to consume excessive computational resources and can take an excessive amount of time. Conversely, training with too little data can lead to an inadequately trained library. By iteratively adjusting training and test sets during iterations of library training based on performance of a library, the library training system can be configured to more efficiently train libraries, thereby optimizing computational resources needed.

### Context for Disclosed Computational Embodiments

Certain embodiments disclosed herein relate to computational systems for generating and/or using machine learning models. Certain embodiments disclosed herein relate to methods for generating and/or using a machine learning model implemented on such systems. A system for generating a machine learning model may also be configured to receive data and instructions such as program code representing physical processes occurring during the semiconductor device fabrication operation. In this manner, a machine learning model is generated or programmed on such system.

Many types of computing systems having any of various computer architectures may be employed as the disclosed systems for implementing machine learning models and algorithms for generating and/or optimizing such models. For example, the systems may include software components executing on one or more general purpose processors or specially designed processors such as Application Specific Integrated Circuits (ASICs) or programmable logic devices (e.g., Field Programmable Gate Arrays (FPGAs)). Further, the systems may be implemented on a single device or distributed across multiple devices. The functions of the computational elements may be merged into one another or further split into multiple sub-modules.

In some embodiments, code executed during generation or execution of a machine learning model on an appropriately programmed system can be embodied in the form of software elements which can be stored in a nonvolatile storage medium (such as optical disk, flash storage device, mobile hard disk, etc.), including a number of instructions for making a computer device (such as personal computers, servers, network equipment, etc.).

At one level a software element is implemented as a set of commands prepared by the programmer/developer. However, the module software that can be executed by the computer hardware is executable code committed to memory using “machine codes” selected from the specific machine language instruction set, or “native instructions,” designed into the hardware processor. The machine language instruction set, or native instruction set, is known to, and essentially built into, the hardware processor(s). This is the “language” by which the system and application software communicates with the hardware processors. Each native instruction is a discrete code that is recognized by the processing architecture and that can specify particular registers for arithmetic, addressing, or control functions, particular memory locations or offsets; and particular addressing modes used to interpret operands. More complex operations are built up by combining these simple native instructions, which are executed sequentially, or as otherwise directed by control flow instructions.

The inter-relationship between the executable software instructions and the hardware processor is structural. In other words, the instructions per se are a series of symbols or numeric values. They do not intrinsically convey any information. It is the processor, which by design was preconfigured to interpret the symbols/numeric values, which imparts meaning to the instructions.

The models used herein may be configured to execute on a single machine at a single location, on multiple machines at a single location, or on multiple machines at multiple locations. When multiple machines are employed, the individual machines may be tailored for their particular tasks. For example, operations requiring large blocks of code and/or significant processing capacity may be implemented on large and/or stationary machines.

In addition, certain embodiments relate to tangible and/or non-transitory computer readable media or computer program products that include program instructions and/or data (including data structures) for performing various computer-implemented operations. Examples of computer-readable media include, but are not limited to, semiconductor memory devices, phase-change devices, magnetic media such as disk drives, magnetic tape, optical media such as CDs, magneto-optical media, and hardware devices that are specially configured to store and perform program instructions, such as read-only memory devices (ROM) and random access memory (RAM). The computer readable media may be directly controlled by an end user or the media may be indirectly controlled by the end user. Examples of directly controlled media include the media located at a user facility and/or media that are not shared with other entities. Examples of indirectly controlled media include media that is indirectly accessible to the user via an external network and/or via a service providing shared resources such as the “cloud.” Examples of program instructions include both machine code, such as produced by a compiler, and files containing higher level code that may be executed by the computer using an interpreter.

In various embodiments, the data or information employed in the disclosed methods and apparatus is provided in an electronic format. Such data or information may include in situ measurements, ex situ measurements, model parameter values, and the like. As used herein, data or other information provided in electronic format is available for storage on a machine and transmission between machines. Conventionally, data in electronic format is provided digitally and may be stored as bits and/or bytes in various data structures, lists, databases, etc. The data may be embodied electronically, optically, etc.

In some embodiments, a machine learning model can each be viewed as a form of application software that interfaces with a user and with system software. System software typically interfaces with computer hardware and associated memory. In some embodiments, the system software includes operating system software and/or firmware, as well as any middleware and drivers installed in the system. The system software provides basic non-task-specific functions of the computer. In contrast, the modules and other application software are used to accomplish specific tasks. Each native instruction for a module is stored in a memory device and is represented by a numeric value.

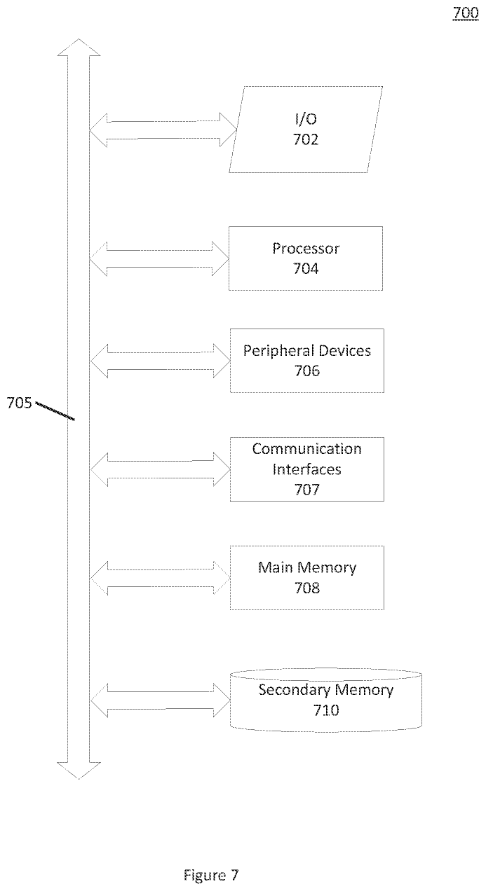

An example computer system 700 is depicted in FIG. 7. As shown, computer system 700 includes an input/output subsystem 702, which may implement an interface for interacting with human users and/or other computer systems depending upon the application. Embodiments of the disclosure may be implemented in program code on system 700 with I/O subsystem 702 used to receive input program statements and/or data from a human user (e.g., via a GUI or keyboard) and to display them back to the user. The I/O subsystem 702 may include, e.g., a keyboard, mouse, graphical user interface, touchscreen, or other interfaces for input, and, e.g., an LED or other flat screen display, or other interfaces for output.

Communication interfaces 707 can include any suitable components or circuitry used for communication using any suitable communication network (e.g., the Internet, an intranet, a wide-area network (WAN), a local-area network (LAN), a wireless network, a virtual private network (VPN), and/or any other suitable type of communication network). For example, communication interfaces 707 can include network interface card circuitry, wireless communication circuitry, etc.

Program code may be stored in non-transitory media such as secondary memory 710 or memory 708 or both. In some embodiments, secondary memory 710 can be persistent storage. One or more processors 704 reads program code from one or more non-transitory media and executes the code to enable the computer system to accomplish the methods performed by the embodiments herein, such as those involved with generating or using a process simulation model as described herein. Those skilled in the art will understand that the processor may accept source code, such as statements for executing training and/or modelling operations, and interpret or compile the source code into machine code that is understandable at the hardware gate level of the processor. A bus 705 couples the I/O subsystem 702, the processor 704, peripheral devices 706, communication interfaces 707, memory 708, and secondary memory 710.

Various computational elements including processors, memory, instructions, routines, models, or other components may be described or claimed as “configured to” perform a task or tasks. In such contexts, the phrase “configured to” is used to connote structure by indicating that the component includes structure (e.g., stored instructions, circuitry, etc.) that performs the task or tasks during operation. As such, the unit/circuit/component can be said to be configured to perform the task even when the specified component is not necessarily currently operational (e.g., is not on).

The components used with the “configured to” language may refer to hardware—for example, circuits, memory storing program instructions executable to implement the operation, etc. Additionally, “configured to” can refer to generic structure (e.g., generic circuitry) that is manipulated by software and/or firmware (e.g., an FPGA or a general-purpose processor executing software) to operate in manner that is capable of performing the recited task(s). Additionally, “configured to” can refer to one or more memories or memory elements storing computer executable instructions for performing the recited task(s). Such memory elements may include memory on a computer chip having processing logic. In some contexts, “configured to” may also include adapting a manufacturing process (e.g., a semiconductor fabrication facility) to fabricate devices (e.g., integrated circuits) that are adapted to implement or perform one or more tasks.

### CONCLUSION

In the description, numerous specific details were set forth in order to provide a thorough understanding of the presented embodiments. The disclosed embodiments may be practiced without some or all of these specific details. In other instances, well-known process operations were not described in detail to not unnecessarily obscure the disclosed embodiments. While the disclosed embodiments were described in conjunction with the specific embodiments, it will be understood that the specific embodiments are not intended to limit the disclosed embodiments.

Unless otherwise indicated, the method operations and device features disclosed herein involves techniques and apparatus commonly used in metrology, semiconductor device fabrication technology, software design and programming, and statistics, which are within the skill of the art.

Unless defined otherwise herein, all technical and scientific terms used herein have the same meaning as commonly understood by one of ordinary skill in the art. Various scientific dictionaries that include the terms included herein are well known and available to those in the art. Although any methods and materials similar or equivalent to those described herein find use in the practice or testing of the embodiments disclosed herein, some methods and materials are described.

Numeric ranges are inclusive of the numbers defining the range. It is intended that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

The headings provided herein are not intended to limit the disclosure.

As used herein, the singular terms “a,” “an,” and “the” include the plural reference unless the context clearly indicates otherwise. The term “or” as used herein, refers to a non-exclusive or, unless otherwise indicated.

1. A computer program product for adaptive model training, the computer program product comprising a non-transitory computer readable medium on which is provided computer-executable instructions for:
receiving, from a plurality of process chambers, ex situ data associated with wafers fabricated using the plurality of process chambers and in situ measurements, wherein the plurality of process chambers use a first machine learning model for process control during fabrication of wafers by the plurality of process chambers, wherein the first machine learning model is used to predict the ex situ data using the in situ measurements, and wherein the ex situ data for a wafer indicates a characteristic of the wafer post-fabrication;
calculating a metric indicating an error associated with the first machine learning model using the ex situ data from the plurality of process chambers;
determining whether to update the first machine learning model based on the metric indicating the error; and
in response to determining that the first machine learning model is to be updated, generating a second machine learning model using the ex situ data and the in situ measurements received from the plurality of process chambers, wherein the first machine learning model and the second machine learning model are evaluated using a test set that includes ex situ data collected before the determination that the first machine learning model is to be updated and ex situ data collected after the determination that the first machine learning model is to be updated.

2. The computer program product of claim 1, wherein the ex situ data is ex situ metrology data measured post-fabrication for a subset of fabricated wafers.

3. The computer program product of claim 1, wherein the ex situ data includes geometric information related to features of a wafer.

4. The computer program product of claim 3, wherein the ex situ data includes Optical Critical Dimension (OCD) information that indicates a depth of the features of the wafer.

5. The computer program product of claim 4, wherein the ex situ data comprises an etch depth.

6. The computer program product of claim 4, wherein the first machine learning model and the second machine learning model are each used to generate predicted OCD values using the in situ measurements.

7. The computer program product of claim 1, wherein the metric indicating the error comprises a cumulative sum of errors of the plurality of process chambers.

8. The computer program product of claim 7, wherein determining whether to update the first machine learning model comprises determining whether the cumulative sum of errors exceeds a control threshold.

9. The computer program product of claim 1, wherein the metric indicating the error comprises a variance of errors of the plurality of process chambers.

10. The computer program product of claim 9, wherein determining whether to update the first machine learning model comprises determining whether the variance of errors exceeds a control threshold.

11. The computer program product of claim 1, wherein determining whether to update the first machine learning model comprises determining that a cumulative sum of error of the plurality of process chambers exceeds a control threshold and that a variance of errors of the plurality of process chambers exceeds the control threshold.

12. The computer program product of claim 1, wherein generating the second machine learning model comprises training a machine learning model using a training set constructed from the ex situ data received from the plurality of process chambers and the in situ measurements received from the plurality of process chambers.

13. The computer program product of claim 12, wherein the in situ measurements comprise reflectance data.

14. The computer program product of claim 1, further comprising instructions for:
determining whether the second machine learning model satisfies criteria to be deployed to the plurality of process chambers; and
in response to determining that the second machine learning model satisfies the criteria to be deployed to the plurality of process chambers, transmitting the second machine learning model to each of the plurality of process chambers.

15. The computer program product of claim 14, wherein determining whether the second machine learning model satisfies the criteria to be deployed comprises evaluating the first machine learning model and the second machine learning model on the test set, and wherein the test set comprises the ex situ data and in situ measurements.

16. The computer program product of claim 15, wherein the criteria comprises better predictive performance of the second machine learning model on the test set of ex situ data and in situ measurements compared to the first machine learning model.

17. (canceled)

18. (canceled)

19. The computer program product of claim 14, wherein determining whether the second machine learning model satisfies the criteria to be deployed comprises determining that an error of the second machine learning model in predicting ex situ data included in a test set is below a threshold.

20. The computer program product of claim 14, further comprising instructions for:
(i) in response to determining that the second machine learning model does not satisfy criteria to be deployed to the plurality of process chambers, generating a third machine learning model;
(ii) determining whether the third machine learning model satisfies the criteria to be deployed to the plurality of process chambers;
repeating (i) and (ii) until it is determined that the third machine learning model satisfies the criteria to be deployed to the plurality of process chambers; and
in response to determining that the third machine learning model satisfies the criteria to be deployed to the plurality of process chambers, transmitting the third machine learning model to each of the plurality of process chambers.

21. The computer program product of claim 20, wherein repeating (i) and (ii) until it is determined that the third machine learning model satisfies the criteria to be deployed comprises repeating (i) and (ii) until it is determined that the third machine learning model is optimal.

22. The computer program product of claim 20, wherein a training set used to generate the second machine learning model is smaller than a training set used to generate the third machine learning model.

23. The computer program product of claim 22, wherein the training set used to generate the third machine learning model comprises newer ex situ data and in situ measurements than the training set used to generate the second machine learning model.

24. A computer program product for using adaptively trained models, the computer program product comprising a non-transitory readable medium on which is provided computer-executable instructions for
transmitting, to a model training system, ex situ metrology data corresponding to a wafer fabricated using a first machine learning model received from the model training system, wherein the first machine learning model is used for process control of a process chamber that fabricated the wafer,
receiving, from the model training system, a second machine learning model for use in process control of the process chamber, wherein the second machine learning model was generated by the model training system using the ex situ metrology data received from a plurality of process chambers and in situ on-wafer optical data measured by the plurality of process chambers; and
replacing the first machine learning model with the second machine learning model, wherein the first machine learning model and the second machine learning model were evaluated using a test set that includes ex situ data collected before a determination that the first machine learning model is to be updated and ex situ data collected after the determination that the first machine learning model is to be updated.

25. The computer program product of claim 24, further comprising instructions for receiving, from the model training system, a message that an error associated with the first machine learning model has exceeded a threshold.

26. The computer program product of claim 24, further comprising instructions for transmitting, to the model training system, second ex situ metrology data corresponding to a second wafer fabricated using the first machine learning model prior to receiving the second machine learning model from the model training system.

27. The computer program product of claim 26, wherein the ex situ metrology data is used to determine that an error associated with the first machine learning model has exceeded a threshold, and wherein the second ex situ metrology data is used to determine that the second machine learning model is to replace the first machine learning model.
